(19) United States
(12) Patent Application Publication
(10) Pub. No.: US 2014/0088911 A1
(43) Pub. Date: Mar. 27, 2014

(54) VLSI Circuit Verification

(71) Applicants: Avi Rabinovich, Kiryat Motzkin (IL); Nadav Cohen, Yavne (IL); Gilad Cohen, Rehovot (IL); Genady Okrain, Rishon Lezion (IL); Aviad Levy, Yavne (IL)

(72) Inventors: Avi Rabinovich, Kiryat Motzkin (IL); Nadav Cohen, Yavne (IL); Gilad Cohen, Rehovot (IL); Genady Okrain, Rishon Lezion (IL); Aviad Levy, Yavne (IL)

(73) Assignee: CIGOL DIGITAL SYSTEMS LTD., Yokneam (IL)

(21) Appl. No.: 14/116,776

(22) PCT Filed: May 24, 2012
(86) PCT No.: PCT/IB12/52604

§ 371 Date: Nov. 11, 2013

Related U.S. Application Data
(60) Provisional application No. 61/491,205, filed on May 29, 2011.

(51) Int. Cl. G01R 31/28

(52) U.S. Cl. CPC G01R 31/2851
USPC 702/117

(57) ABSTRACT

A method of connecting to an integrated circuit. A target integrated circuit (102) is provided with an embedded agent (104) for exporting signals. While the target integrated circuit (102) is operating, data signals from one or more collection points (252) in the integrated circuit (102) are collected by the embedded agent (104), at least at a clock rate of operation of the integrated circuit at the one or more collection points (252), in parallel to the target circuit (102) operation. The collected data signals are inserted into packets, by the embedded agent (104) and the packets are transmitted to a unit external to the integrated circuit, in real time.

### CROSS-REFERENCE TO RELATED APPLICATION

This application claims the benefit under 35 USC 119(e) of U.S. Provisional Patent Application 61/491,205, filed May 29, 2011, which is incorporated herein by reference.

### FIELD OF THE INVENTION

The present invention relates generally to integrated circuits and particularly to design verification of integrated circuits.

### BACKGROUND OF THE INVENTION

Integrated circuits have become very complex, sometimes including millions of transistors in a single integrated circuit (IC). Field programmable gate arrays (FPGA) are integrated circuits including a large number of transistors which the user can configure to perform a desired task by adjusting the connections between the transistors. An FPGA can be reconfigured repeatedly, allowing a user to test the operation of the FPGA and correct errors. Users generally define a required circuit design in a hardware definition language (HDL) and a compiler converts the user design into a layout which is then configured into the FPGA.

Integrated circuits use various methods in order to communicate with external units.

U.S. Pat. No. 7,187,709 to Menon et al., describes a high speed configurable transceiver architecture.

U.S. Pat. No. 7,751,442 to Chang et al. describes using a serial Ethernet device to device interconnection.

U.S. Pat. No. 7,500,060 describes using a hardware stack for communication with an FPGA based embedded processor system on chip (SoC).

Due to their complexity it is important to verify correctness of the design of integrated circuits.

A product specification of Xilinx, dated Apr. 19, 2010, relating to Chipscope Pro Integrated Logic Analyzer describes an integrated logic analyzer (ILA) which can be used to monitor any internal signal in a designed FPGA. The ILA comprises a core embedded in the FPGA with the user's logic. The embedded core of the ILA includes a large buffer in which monitored signals are stored. After the buffer is filled, the stored signals are uploaded to ILA software.

U.S. Pat. No. 6,760,898 describes inserting probe points in an FPGA system on chip.

US patent publication 2012/0011411, titled “On-Chip Service Processor” describes embedding a service processor unit (SPU) into a tested integrated circuit. The SPU may set values in the user logic and collects monitored signals in a buffer at the rate of the user logic. The Stored signals from the buffer are exported at an external clock rate.

U.S. Pat. No. 7,882,465 to Li et al., titled: “FPGA and Method and System for configuring and Debugging a FPGA”, describes an FPGA with a probe signal selection unit and a high speed serial transceiver configured to transmit a probed signal to an external unit.

U.S. Pat. No. 7,533,315 to Han et al. describes an integrated circuit with scan based debugging.

### SUMMARY

Embodiments of the present invention that are described hereinbelow provide methods and systems for non-intrusive input/output of operation rate signals to/from an integrated circuit, for analysis, testing, verification, monitoring and/or debugging of the integrated circuit. The non-intrusive input/output signals may be used during early design stages before commercial production and/or after production, for example for quality assurance, wafer testing and/or for field testing after the integrated circuit is supplied to a customer.

There is therefore provided in accordance with an embodiment of the present invention a method of connecting to an integrated circuit, comprising providing a target integrated circuit with an embedded agent for exporting signals, operating the integrated circuit, collecting data signals from one or more collection points in the integrated circuit, by the embedded agent, at least at a clock rate of operation of the integrated circuit at the one or more collection points, in parallel to the target circuit operation, inserting the collected data signals into packets, by the embedded agent; and transmitting the packets to a unit external to the integrated circuit, in real time.

Optionally, the method includes receiving, by the embedded agent, packets of data from the external unit and placing data signals from the packets onto one or more drive points defined in the integrated circuit. Optionally, placing data signals from the packets onto one or more drive points defined in the integrated circuit is performed at a rate of at least one tenth of the clock rate at the drive points. Optionally, the method includes applying an error detection check to the received packets, by the embedded agent. Optionally, the method includes applying an error correction method to received packets detected as having errors. Optionally, the method includes receiving by the embedded agent of reordered packets from the external unit, reordering the packets according to identification numbers in the packets, and placing signals from the packets onto one or more drive points defined in the circuit design. Optionally, the method includes compressing the signals from the collection points before transmission to the external unit.

Optionally, compressing the signals comprises replacing repeated sequences by metadata and/or replacing a window of data by metadata which is a function of a previous window of data. Optionally, the one or more collection points comprise a plurality of collection points operating at a plurality of different clock rates. Optionally, the method includes continuously calculating temporal rates of the collection points by the external unit and presenting the signals from the different points on a shared timeline. Optionally, the embedded agent comprises a plurality of serial transceivers for communication with the external unit. Optionally, the plurality of serial transceivers include transceivers configured to operate simultaneously in accordance with a plurality of different protocols. Optionally, configuring the integrated circuit with the embedded agent includes receiving, by a processor, from a user, indications of collection and drive points, estimating, by the processor, a required bandwidth for transmission and reception of data for the indicated points, and selecting, by the processor, serial interfaces for the embedded agent responsively to the estimated required bandwidth. Optionally, selecting serial interfaces comprises selecting a number of interfaces.

Optionally, selecting serial interfaces comprises selecting a data rate of one or more of the interfaces. Optionally, selecting serial interfaces comprises selecting responsively to the clock rates at the indicated points. Optionally, configuring the integrated circuit with the embedded agent includes receiving, by a processor, from a user, indications of collection and drive points, and selecting, by the processor, sizes of respective buffers for each of the points. Optionally, selecting sizes of respective buffers for the points comprises selecting for the size for each point responsively to a clock rate of the point. Optionally, the method includes receiving by the embedded agent drive signals from the external unit and forwarding the drive signals to one or more additional integrated circuits.

Optionally, configuring the integrated circuit comprises receiving, by a processor, from a user, indication of one or more collection points, receiving, by the processor, indication of one or more keep points, preparing for the integrated circuit a layout with connections between the one or more collection points and the embedded agent and with circuit preparations allowing changing the layout to connect the embedded agent to at least one of the keep points instead of at least one of the collection points, without requiring regeneration of the layout through synthesis, placement or routing and configuring the integrated circuit with the prepared layout.

Optionally, the method includes changing the layout to connect the embedded agent to at least one of the keep points instead of at least one of the collection points, by a physical engineering change order, configuring the integrated circuit with the new layout and repeating the operating of the circuit design and the collecting of signals for the new layout.

Optionally, the embedded agent includes respective buffers for each collection point in the circuit design and comprising transmitting periodic status packets, including indications of the occupancy of the buffers, from the embedded agent to the external unit.

Optionally, inserting the collected signals into packets comprises inserting into packets with a header including an address field identifying a unit of the embedded agent. Optionally, the embedded agent is implemented by a hardware design. Optionally, the embedded agent including all on-chip memory for storing collected signals occupies less than 2% of the area of the integrated circuit. In some embodiments, the embedded agent includes for each collection point a respective buffer which has memory sufficient for storing data collected in no more than 50 clock cycles. Optionally, the method includes receiving by the embedded agent collected signals from one or more additional integrated circuits and forwarding the received signals to the external unit.

There is further provided in accordance with an embodiment of the present invention, an integrated circuit, including a target user circuit, an embedded agent including: one or more collectors connected to respective collection points in the user circuit, configured to collect signals from the respective collection points, at least at a clock rate of operation of the integrated circuit at the collection point, and to insert the collected signals into packets and one or more transmitters configured to transmit packets from the one or more collectors to a unit external to the integrated circuit, in real time.

Optionally, the integrated circuit includes one or more receivers configured to receive packets from one or more external units; and one or more drivers configured to receive packets from the one or more receivers, extract signals from the packets and place them on respective drive points of the user circuit.

In some embodiments, the one or more collectors comprise buffers having a total capacity for each collection point, of less than 5 Kbytes. Optionally, the embedded agent comprises an error detection unit adapted to add an error detection code to packets generated by the collectors. In some embodiments, the embedded agent comprises a compression unit configured to compress signals collected by the collectors. Optionally, the one or more transceivers comprise a plurality of serial transceivers configured to operate simultaneously in accordance with a plurality of different protocols.

There is further provided in accordance with an embodiment of the present invention, a method of connecting to an integrated circuit, including providing a target integrated circuit with an embedded agent for exporting internal signals, operating the integrated circuit, such that a plurality of different areas of the integrated circuit operate in different clock domains, collecting data signals from a plurality of collection points in respective different areas having different clock domains, at least at the clock rates of the collection points, in parallel to the circuit operation and transmitting the collected data signals to a unit external to the integrated circuit, in real time.

Optionally, the embedded agent includes a respective buffer in which the signals are buffered until they are transmitted, for each collection point, and wherein at least two of the buffers have different sizes.

There is further provided in accordance with an embodiment of the present invention, a method of connecting to internal points of an integrated circuit, comprising providing an integrated circuit, embedding an agent in the circuit design, operating the integrated circuit, collecting signals from one or more collection points in the integrated circuit, by the embedded agent, at least at a clock rate of operation of the circuit at the collection point, in parallel to the circuit operation and transmitting the signals to a unit external to the FPGA, in real time, through a plurality of interfaces operating in accordance with a plurality of different protocols.

There is further provided in accordance with an embodiment of the present invention, a method of non-intrusive output of signals from an integrated circuit, comprising providing a target integrated circuit with an embedded agent for exporting internal signals, the embedded agent including a triggering unit, operating the integrated circuit, collecting signals from one or more collection points at least at the operation rate of the integrated circuit, in parallel to the circuit operation; and transmitting the collected signals to a unit external to the integrated circuit, in real time, wherein at least one of the collecting and transmitting is initiated or terminated by the triggering unit.

Optionally, the method includes monitoring the signals on one or more points of the integrated circuit by the triggering unit and initiating or terminating the collecting or the transmitting, responsively to identifying a user-selected sequence on the one or more points.

In some embodiments, monitoring the one or more points comprises monitoring at least one point is different from the one or more collection points from which signals are collected.

Optionally, monitoring the one or more points comprises monitoring only points different form the one or more collection points from which signals are collected.

Optionally, collecting the signals is performed continuously and wherein transmitting the collected signals is initiated responsive to identification of an event by the triggering unit.

There is further provided in accordance with an embodiment of the present invention, a method of connecting to internal points of a Field programmable Gate array (FPGA circuit), including providing a target design, receiving, by a processor, from a user, indication of one or more collection points in the circuit design, receiving, by the processor, indication of one or more keep points in the circuit design, preparing for the FPGA a layout with connections between the one or more collection points and the embedded agent and with circuit preparations allowing changing the layout to connect the embedded agent to at least one of the keep points instead of at least one of the collection points, without requiring re-synthesis of the layout, configuring the FPGA with the prepared layout, operating the circuit design in the FPGA, collecting data signals from one or more collection points in the circuit design in the FPGA, by the embedded agent, at least at a clock rate of operation of the circuit at the collection point, in parallel to the circuit operation; and transmitting the data signals to another location in the FPGA or to a unit external to the FPGA, in real time.

Optionally, preparing for the FPGA with circuit comprises preparing with preparations allowing changing the layout to connect the embedded agent to at least one of the keep points instead of at least one of the collection points, without requiring repeating the placement of the layout.

There is further provided in accordance with an embodiment of the present invention, an intermediate unit for non-intrusive output of signals from an integrated circuit, including an integrated circuit interface configured to communicate with an embedded agent in the integrated circuit, and to receive from the embedded agent signals collected from one or more points of the integrated circuit at operation rate, a buffer configured to store signals received through the integrated circuit interface, a computer interface configured to transfer signals from the buffer to a computer; and a controller configured to control transmission of signals through the integrated circuit interface and the computer interface, to receive through the integrated circuit interface status data or instructions and to operate in response to the received status data or instructions immediately, such that changes in transmission of the signals required by the received status data or instructions are performed within less than 1 microsecond from reception of the status data or instructions by the integrated circuit interface.

Optionally, the controller comprises a plurality of hardware implemented DMAs. Optionally, changes in transmission of the signals required by the received status data or instructions are performed within less than 100 nanoseconds from reception of the status data or instructions by the integrated circuit interface.

Optionally, the integrated circuit interface and the computer interface are implemented in hardware design. Optionally, the computer interface is configured to communicate concurrently with a plurality of computers. In some embodiments, the controller is configured to always transfer data signals through the computer interface in chunks of a plurality of whole packets received through the integrated circuit interface. Optionally, the intermediate unit does not perform any analysis tasks on the signals it receives.

### BRIEF DESCRIPTION OF THE DRAWINGS

FIG. 1 is a schematic block diagram of a Field Programmable Gate Array (FPGA) verification system, in accordance with an embodiment of the invention;

FIG. 2 is a schematic illustration of a target FPGA with an emphasis on an embedded agent therein, in accordance with an embodiment of the invention;

FIG. 3 is a schematic illustration of a packet format used in accordance with an embodiment of the invention;

FIG. 4 is a flowchart of acts performed by a builder software in preparation for testing and/or validation of a target FPGA, in accordance with an embodiment of the invention;

FIG. 5 is a schematic illustration of a target FPGA with connections to collectors, in accordance with an embodiment of the invention; and

FIG. 6 is schematic illustration of an FPGA testing setup, in accordance with an embodiment of the invention.

### DETAILED DESCRIPTION OF EMBODIMENTS

An aspect of some embodiments of the invention relates to a system for non-intrusive output of signals from an integrated circuit, including an on-chip embedded core, which senses at operation rates signal values at one or more desired points in the integrated circuit and transmits the sensed signals to an external unit of the system in real time, in packets, using a protocol stack. Transmitting the sensed signals in packets through a protocol stack, provides the various advantages of packet transmissions and use of a protocol stack, including flexibility of design, error protection, flexibility of transmissions and/or ease of interleaving data from different sources, such as control transmissions with data transmissions and/or sensed signals from different clock domains.

In some embodiments, the on-chip embedded core is also configured to receive values to be set to desired points of the integrated circuit, in real time, from the external unit.

Optionally, the protocol stack includes a data compression stage, optionally applying a lossless compression. In some embodiments of the invention, the compression stage performs a bit-wise compression, compressing signals relating to different points on the chip separately. The compression optionally includes identifying repetitions, patterns and/or gaps in the data and representing them by lower volume data, optionally embedded as metadata in the data. In some embodiments, in performing the compression, a current window of data is compared to one or more previous data windows in the compressed data stream. When the difference between the current window and the previous window is relatively small, the difference between the windows is encoded (e.g., by indicating the locations of the bits that differ) and is transmitted instead of the current window. Various other compression schemes, which provide different tradeoffs between compression performance and integrated circuit area requirements, may be used. The window optionally has a length of at least 8 bytes, at least 16 bytes or even at least 32 bytes, although smaller windows may also be used.

Alternatively or additionally, the protocol stack includes an error correction stage which adds an error correction and/or error detection code, checks received packets for errors and/or correct errors in packets.

The protocol stack is optionally implemented in hardware, using a relatively small portion of the analyzed integrated circuit, for example requiring less than 2%, or even less than 1% of the logic and/or memory of a standard sized FPGA. Stated in other terms, the protocol stack is optionally implemented by several thousand logic cells, generally less than 50,000 logic cells or even less than 10,000 logic cells. The term hardware refers herein to circuits which are designed to perform a specific task, based on their structure. The hardware either does not run software at all or the software does not substantially affect the behavior or operation mode of the circuit.

Optionally, the on-chip transmitter includes a generic link layer transmitter which handles transmission and reception of signals, regardless of the physical layer with which it operates. Thus, the same link layer unit, and higher layer units, may be used in different environments, for transmissions on different physical connections, without needing to change anything but the physical layer unit. In some embodiments of the invention, the link layer may be used with a plurality of different types of physical layer units concurrently in the same circuit.

The on-chip embedded core is optionally configured to transmit, to an external unit, feedback on a rate at which it can currently receive data for setting values of desired points, from the external unit. In some embodiments, the on-chip embedded core is configured to identify cases in which it is receiving data faster than a required on-chip data rate and to urgently transmit a flow control message requesting to stop the transmission. The protocol stack supports low latency flow control to prevent the need for large on-chip buffers of signal values to be set to desired points. Optionally, the on-chip embedded core is configured to transmit both data packets and control packets and to prioritize control packets.

In some embodiments, the on-chip buffer for each drive or collection point is smaller than required for data of 100 clock cycles, 50 clock cycles or even smaller than required for 25 clock cycles.

In some embodiments of the invention, a plurality of integrated circuit chips are connected to a single external unit in a cascaded manner, such that transmissions to one or more of the integrated circuits pass through a different one of the integrated circuits. Cascading the integrated circuits for debugging allows debugging a plurality of integrated circuits together, for example when a plurality of Field Programmable Gate Array (FPGA) integrated circuits simulate a single application specific integrated circuit (ASIC), for testing.

Optionally, the signals are transmitted between the embedded unit on the chip and the external unit over one or more serial lines passing through one or more pins of the chip. In some embodiments, the system is adapted to dynamically adjust the transmission speed on the serial lines according to the current transmission capacity and/or to adjust the number of transmission lines used according to user instructions. Optionally, the system suggests the number of transmission lines to be used and/or their speeds according to the user defined amount of data to be exported and/or user settings on error chances.

An aspect of some embodiments of the invention relates to a system for integrated circuit analysis including an on-chip embedded core, which senses at operation rates signal values at a plurality of points in different clock domains of the integrated circuit and transmits the sensed signals to an external unit of the system in real time. Providing signals from different clock domains at operation rate allows more flexibility in analysis of the integrated circuit.

The signals are optionally sampled at the rate of the local clock of the circuit generating the sampled signals. Alternatively, the signals are sampled by a sampling circuit controlled by a separate clock having a rate of the order of the clock of the circuit generating the signals. Further alternatively, the signals are sampled at a substantially higher rate than the rate of the sampled signals. This option may be used, for example, when a single sampling clock is used to sample signals from a plurality of clock domains. The use of a single sampling clock is simpler and in accordance with this alternative is worth the extra unnecessary high rate sampling of one or more of the sampled signals.

Optionally, the on-chip embedded core includes a central unit which continuously measures the temporal rate of the different clock domains of the integrated circuit with respect to a central clock, having a higher frequency than the frequencies of the different clock domains. The external unit optionally presents to the user sensed signals from distinct clock domains on the same synchronized timeline.

An aspect of some embodiments of the invention relates to a system for non-intrusive output of signals from an integrated circuit, which includes an internal triggering unit which triggers the output of the signals. Internal triggering of the output of the signals allows to reduce the amount of signals that need to be exported and thus allows exporting larger amounts of data of interest.

In some embodiments, the internal triggering of the output of a first signal is triggered in response to examination of a second signal, different from the first. Thus, there is no need to output both the first and second signals for analysis.

An aspect of some embodiments of the invention relates to a method of implanting a debugging unit on a chip of an integrated circuit. The method includes preparing a HDL description of a debugging unit and embedding the description in a HDL description of a user chip to be tested. Providing the description of the debugging unit in HDL allows for simpler use of the agent at later stages of development or even at deployment.

In some embodiments of the invention, a software tool receives for the integrated circuit indications of points to be connected to the debugging unit and accordingly automatically configures one or more units of the debugging unit, such as buffer sizes, transmitter parameters (e.g., number of transmitters, transmission speeds). Optionally, the processor additionally receives an indication of a desired reliability level and uses this indication in the configuration of the one or more units. In some embodiments of the invention, the software tool parses the integrated circuit and presents it to a user in a graphic user interface (GUI). The software tool optionally allows the user to search and choose collection, triggering and driven points and connects these user-chosen points to the debugging unit.

Optionally, the user may define a set of sensing points larger than can be handled concurrently by the debugging unit. In some embodiments, at least some of the sensing points are connected to multiplexers, controlled from a computer external to the integrated circuit by instructions transmitted to the on-chip embedded core. The user thus selects the points from which signals are sensed dynamically, without reconfiguring the on-chip circuit. In other embodiments, the set of sensing points includes sensing points which are connected to the debugging points and sensing points for future use which reserve a sensing point but cannot be used without a reconfiguration of the on-chip circuit. When desired, a human user may instruct the system to connect one or more of the sensing points for future use to the debugging unit, instead of other sensing points. The layout of the integrated circuit is changed by a physical engineering change order (ECO) changing the connected sensing points, without requiring full recompilation of the integrated circuit, e.g., without performing synthesis, placement and/or routing. Optionally, the integrated circuit also includes a plurality of intermediate nodes connected to the debugging unit, distributed throughout the integrated circuit. When a sensing point needs to be connected to the debugging unit it is connected to one of the intermediate points in its vicinity.

An aspect of some embodiments of the invention relates to a system for non-intrusive output in real time from an integrated circuit, of sensed signals at operation rate. The system uses an intermediate communication unit between the integrated circuit and a computer which analyzes, utilizes and/or displays the sensed signals. Locating an intermediate communication unit between the computer and the integrated circuit allows high rate transmissions and achieves real time transmissions at relatively high operation rates. The intermediate unit optionally does not perform any analysis tasks on the signals. In some embodiments of the invention, the intermediate unit is implemented in hardware, for example using one or more DMAs.

The intermediate communication unit is optionally configured to receive control instructions and/or status data from the integrated circuit and operate on them immediately, such that the buffers on the integrated circuit may be relatively small. For example, when required to stop transferring data to the integrated circuit and/or to begin retrieving data from the integrated circuit, the intermediate unit performs the task immediately. Optionally, the intermediate communication unit is configured to operate in response to status data or instructions within less than 100, less than 50 or even less than 20 clock cycles of the integrated circuit, for clock cycles of less than 100 nanoseconds, less than 20 nanoseconds or even less than 5 nanoseconds. Thus, the intermediate communication unit is configured to operate in response to status data or instructions within less than 1 microsecond, less than 0.2 microseconds or even less than 50 nanoseconds.

Optionally, the protocol governing the transmissions between the integrated chip and the intermediate communication unit is defined and/or selected responsive to one or more hardware attributes of the intermediate unit. For example, the size of packets and/or of the payload of packets exchanged between the integrated chip and the intermediate unit is optionally set responsively to the size of records in a memory of the intermediate unit. Alternatively or additionally, the protocol governing the transmissions between the intermediate unit and the computer is selected responsively to one or more hardware attributes of the intermediate unit.

In some embodiments of the invention, the intermediate unit is adapted to communicate with a plurality of computers, for example transmitting the data from the integrated circuit in parallel to a plurality of computers or transmitting different portions of the data to different computers.

### System Overview

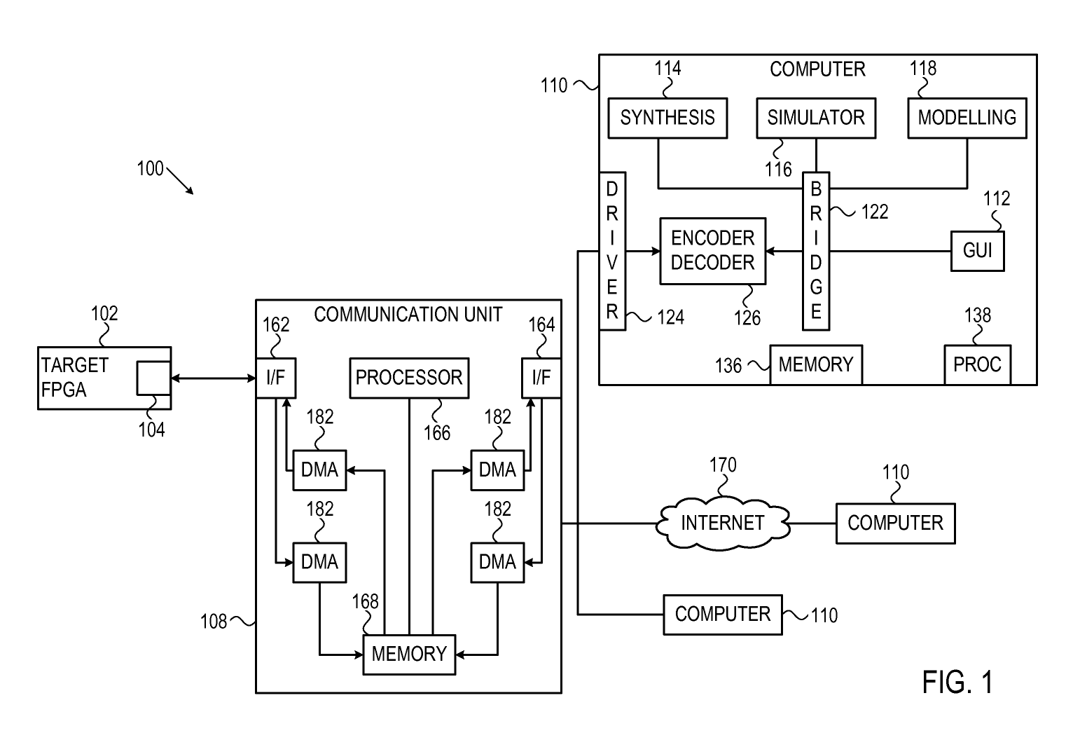

FIG. 1 is a schematic block diagram of a Field Programmable Gate Array (FPGA) verification system 100, in accordance with an embodiment of the invention. System 100 includes a target FPGA 102 which is tested, a computer 110 which serves as a work station for management of the verification and an intermediate communication unit 108, which handles communications between target FPGA 102 and computer 110. An embedded agent 104 is included in the target FPGA 102. The embedded agent collects signals from points of interest in the target FPGA 102 and transmits them toward communication unit 108. In some embodiments, embedded agent 104 also receives drive signals from computer 110, through communication unit 108 and places the drive signals at indicated points in the verified target 102.

Computer 110 is optionally configured with a graphic user interface (GUI) 112 through which a user controls the verification of target FPGA 102. The user may use GUI 112 to define drive and collection points in the integrated circuit and parameters of the embedded agent 104, such as its reliability and/or transmission bandwidth.

Computer 110 is optionally also configured with one or more verification and handling tools, such as a synthesis tool 114, a simulator 116 (e.g., an RTL simulator, a ModelSim tool, Matlab) and/or a modeling tool 118. These tools receive signals collected from target FPGA 102 and accordingly analyze its operation. The tools may also be used to generate drive signals for the analysis. Optionally, the verification is performed using one or more tools used during the design of target FPGA 102, allowing the verification to be performed as a natural continuation of the design and RTL testing.

Computer 110 is optionally configured with a bridge 122 and a driver 124 for communication with embedded agent 104. In some embodiments of the invention, computer 110 is configured with an encoder and/or decoder unit 126, which encodes and/or decodes signals exchanged with embedded agent 104.

Computer 110 typically comprises a general-purpose computer or a cluster of such computers, with suitable interfaces, one or more processors 138, and software for carrying out the functions that are described herein, stored, for example, in a memory 136. The software may be downloaded to computer 110 in electronic form, over a network, for example. Alternatively or additionally, the software may be held on tangible, non-transitory storage media, such as optical, magnetic, or electronic memory media. Further alternatively or additionally, at least some of the functions of computer 110 may be performed by dedicated or programmable hardware logic circuits. For the sake of simplicity and clarity, only those elements of computer 110 that are essential to an understanding of the present invention are shown in the figures.

It is noted that system 100 may operate with a single computer 110 or a plurality of computers 110 in different locations. In some embodiments, one or more of the computers 110 may be connected to intermediate communication unit 108 through a wide area network, for example the Internet 170 or an intranet. Thus, the user can control verification and/or testing of target FPGA 102 from a remote location. Optionally, the user may request that all collected data signals from target FPGA 102 be transmitted to each of a plurality of computers 110, for example to allow collaborative work of a plurality of users who analyze the data from target FPGA 102 in parallel and/or when different computers are configured with different analysis tools. Alternatively or additionally, signals from different collection points in target FPGA 102 are transmitted by communication unit 108 to different computers 110.

### Embedded Agent

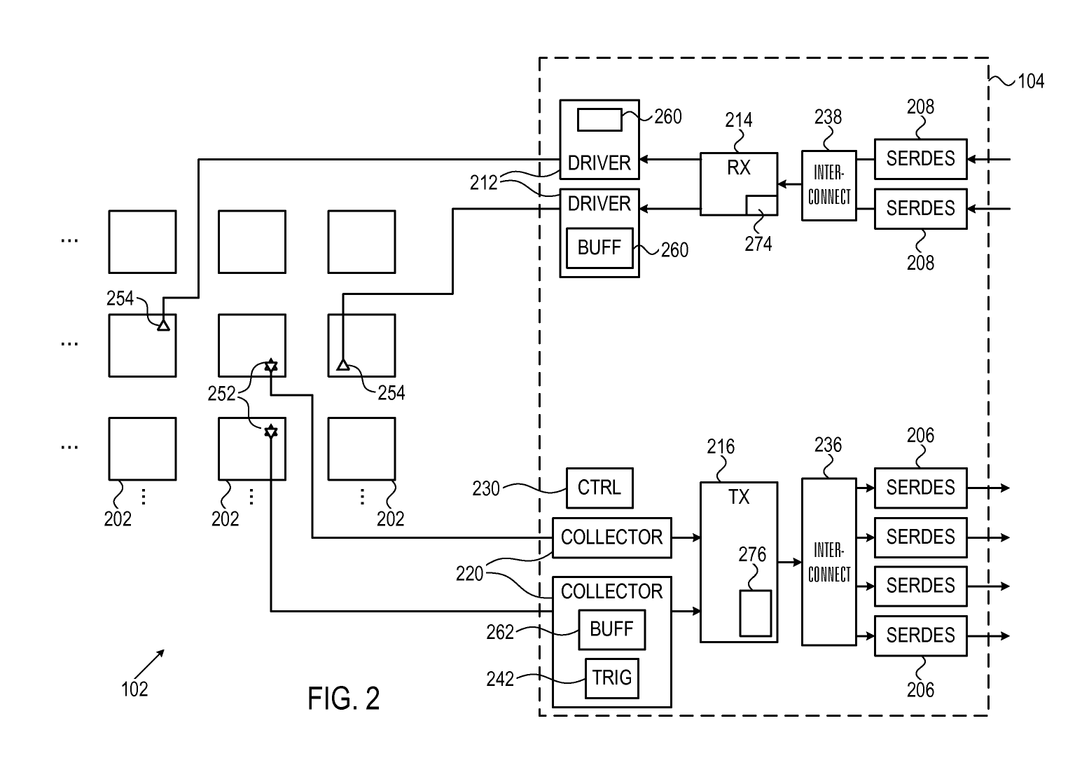

FIG. 2 is a schematic illustration of target FPGA 102 with an emphasis on embedded agent 104, in accordance with an embodiment of the invention. Target FPGA 102 includes a plurality of cells 202 of gates, which are configured by the user to perform a desired task, as is known in the art. Embedded agent 104 is placed in target FPGA 102 in order to collect signals from desired collection points 252 in cells 202 and export them in real time to computer 110 (FIG. 1) for analysis, and optionally also to receive signals from computer 110 and place them in real time at desired drive points 254. Generally, target FPGA 102 includes a large number of cells 202, thousands, tens of thousands, hundreds of thousands or even millions, but for simplicity of FIG. 2 only a small number are shown. In addition, to aid in the present discussion, FIG. 2 has emphasis on the details of embedded agent 104, although agent 104 optionally covers only a small portion of the area of target FPGA 102, possibly less than 10%, less than 1% or even less than 0.1%.

For reception and application of driving signals, embedded agent 104 optionally includes one or more high speed serializer/deserializer (Serdes) input transceivers 208, a protocol interconnect unit 238, a receiver 214 and one or more drivers 212.

In the opposite direction, one or more collectors 220 collect signals from desired collection points 252, and pass them to a transmitter 216, which organizes them in packets. The packets are provided to one or more output protocol interconnect units 236 which transmit them through one or more transceivers 206 to communication unit 108. These elements of agent 104 implement a protocol stack for transmission and reception of signals.

Transceivers 206 and 208 perform tasks of a physical signaling layer. The signaling layer is governed by a suitable protocol, such as low-voltage differential signaling (LDVS) or Gigabit transceiver (GX), although other protocols may be used. In some embodiments of the invention, all of transceivers 206 and 208 operate according to the same protocol. Alternatively, different transceivers operate according to different protocols. Each transceiver 206, 208 optionally corresponds to a single pin of the chip of integrated circuit 102, allocated to agent 104. Transceivers 206, 208 optionally operate at rates of between about 1-10 Gbits per second, although higher or lower rates may also be used. The number of transceivers 206 and 208 included in embedded agent 104 is optionally selected at the time of configuration of target FPGA 102, according to the required communication bandwidth between embedded agent 104 and communication unit 108. In some embodiments, the required bandwidth is estimated based on the number of drive and collection points and their clock rates.

It is noted that transceivers 206 and 208 may be physically designed for one way transmission or reception, in which case they may be referred to as transmitters or receivers, or may be two way transmission transceivers, used for transmission in only a single direction or in both directions.

Interconnect units 236, 238 manage the transmissions through transceivers 206, 208, respectively, according to a physical interconnect layer, such as Interlaken or SPI-4.2. In some embodiments, a single interconnect unit 238 handles all of transceivers 208, such that receiver 214 receives packets from a single entity. Alternatively, agent 104 may include a plurality of interconnect units 238, possibly a single unit 238 for each transceiver 208, for example when different transceivers operate in accordance with different protocols. Similarly, one interconnect unit 236 may be used for all of transceivers 206 or several interconnect units 236 may be used.

Transceivers 206, interconnect unit 236 and/or transmitter 216 are optionally configured to transmit packets according to the order in which they are received. Alternatively or additionally, some types of packets, for example control packets and/or status packets, are given priority over other packets. Giving priority to control and/or status packets reduces the latency of communications between agent 104 and communication unit 108 and thus reduces the required size of the buffers 260, 262 in agent 104.

Above the interconnect layer, the protocol stack includes a packet switch and/or router, implemented by receiver 214 and transmitter 216. Receiver 214 directs received packets to their intended driver 212 and transmitter 216 collects packets from the various collectors 220. Receiver 214 optionally parses the headers of the received packets to determine their destination. The signals in correctly received data packets are optionally transferred to one of drivers 212, identified by a destination field in their header. The receiving driver 212, applies the received signals to a corresponding drive point 254. Correctly received control packets are transferred to a controller 230. In embodiments in which more than a single reception interconnect unit 238 is used, receiver 214 aggregates the packets from the different interconnect units 238. Similarly, when a plurality of transmission interconnect units 236 are used, transmitter 216 manages the distribution of the packets between the interconnect units 236.

In some embodiments of the invention, receiver 214 is configured to verify that the received packets of each buffer 260 have consecutive packet numbers in their header and to request retransmission of data packets not received. Optionally, receiver 214 includes a packet buffer 274 in which packets are stored while waiting for retransmission of preceding packets. Alternatively or additionally, the data of later packets received before earlier packets not yet received is stored within the buffer 260 in a manner leaving a gap for the forthcoming missing data. The retransmission requests are optionally given priority over all other packets to ensure the retransmitted data is received on time. Alternatively or additionally to requesting retransmission, receiver 214 is configured to correct errors. Optionally, each packet may include redundant information which may be used for error correction, for example in accordance with Reed-Solomon or CRC.

Optionally, different error correction/detection schemes are used for transmitting to agent 104 and from agent 104. In transmitting from agent 104, an error detection/correction code which is relatively simple to calculate is used, with a relatively complex error detection/correction method at the receiver, as the error correction/detection is performed by communication unit 108 and/or computer 110. On the other hand, for packets transmitted to agent 104, a relatively complex error detection/correction code, which allows checking for errors and/or correcting them with minimal resources, is used. Alternatively, the same error correction/detection method is used in both directions.

In some embodiments, a CRC code is added to the transmitted packets and if there is an error, the receiver determines which bit if changed would result in a correct code. Optionally, an algorithm based on the linear nature of the CRC code, having linear complexity, is used to determine the erroneous bit location.

Transmitter 216 is optionally configured to store packets it transmits in a transmission buffer 276 for a short period, for example until an acknowledgement of reception is received or until a predetermined time has passed. Embedded agent 104 is optionally configured to receive retransmission requests from communication unit 108 and respond with retransmission of the requested data. In other embodiments, retransmission is not performed, for example when the connection between agent 104 and communication unit 108 has a very low BER (Bit Error Rate) and/or when an error correction scheme is used.

As is known in the art, different points 252 and 254 may operate at different rates. Buffers 260 and 262 serve to bridge between the particular clock rates of the drive and collection points 252 and 254 on one side and transmitter and receiver 214 and 216 on the other side.

Above the packet switch, the protocol stack includes collectors 220, drivers 212 and controller 230. In some embodiments, transmitter 216 may perform compression, coding and/or error protection tasks (e.g., adding a CRC code) on the transmitted signals. Similarly, receiver 214 may perform decompression/decoding of the received data packets. In some embodiments, receiver 214 also performs an error check on the packet, e.g., CRC checking, to verify it was received correctly and/or may perform error correction.

In some embodiments, the same tasks performed on data received by embedded agent 104 are performed on signals exported by agent 104. For example, agent 104 adds a CRC field to transmitted signals and checks the CRC of received packets. Alternatively, different sets of tasks are applied to transmitted and received signals. For example, compression may be applied only to received signals and not to transmitted signals or different compression methods may be used for the received and transmitted packets.

### Drivers and Collectors

Drivers 212 optionally manage for each drive point 254 a first-in-first-out buffer 260, in which received signals are buffered until their turn to be applied is reached. Drivers 212 optionally extract the payload data from the packets received by receiver 214 and place them in buffer 260. Driver 212 independently extracts signals from buffer 260 and places them at the drive point 254 at the operation rate of the point. Drivers 212 are optionally configured to enter the packets into the buffer according to the order in which they were transmitted, according to the packet number, in case the reception order is different from the transmission order.

Collectors 220 manage for each collection point 252, a buffer 262 in which the signals from the point are accumulated until they are placed in a packet for transmission to computer 110. Collectors 220 continuously collect data from their respective collection points 252 at their respective clock rates.

Drive points 254 and collection points 252 may have a single bit width or a width of a plurality of bits. Drive and collect points are optionally of a width which is a power of 2, e.g., 16, 32, 64, although this is not necessary and the points may have substantially any width. In some embodiments, the drive and collect points have a width of up to 64 bits. If a point having more bits is to be sampled or driven it is optionally defined as a plurality of separate points. In other embodiments, points of widths greater than 64 bits are also allowed. The buffers 260 and 262 are optionally adjusted to the widths of their respective points. Depending on the width of a drive point 254, the packets transmitted to the corresponding driver 212 may include signals for a single clock cycle or for a plurality of clock cycles. Optionally, each packet includes data for only a single drive point 254. Alternatively, a packet may include data for a plurality of drive points 254.

In some embodiments of the invention, each driver 212 operates at a clock rate of the drive points 254 that it drives. Alternatively, the drive signals may be provided at a lower rate than the clock rate at the drive point, optionally providing drive signals at a rate of at least once every thousand, at least once every one hundred or at least once every ten clock cycles, although drive signals may be provided also at lower rates. Similarly, collectors 220 operate at a clock rate of the collection points from which they collect signals. Drivers 212 and collectors 220 may receive a clock signal at their operation rate or higher as known in the art.

Buffers 260 and 262 optionally have a size sufficient to prevent overflows and underflows of data. Optionally, driver buffers 260 have a size sufficient to accumulate data received from communication unit 108 during the time between identifying that the target circuit is not retrieving data, sending a notification to communication unit 108 and stopping the transmission by communication unit 108. As in some embodiments the time required for stopping the transmissions is relatively short, buffers 260 may be relatively small, optionally including memory for data corresponding to less than 100 clock cycles, less than 60 clock cycles or even less than 30 clock cycles or less than 20 clock cycles. For a point with a width of 64 bits, which requires 8 bytes per cycle, buffer 260 is optionally smaller than 5 Kbytes or even not larger than a single Kbyte. In some embodiments of the invention, target FPGA is designed for predetermined memory unit sizes and the smallest memory unit size sufficiently large is used. Optionally, each buffer 260 has a minimal size of at least two packets, or even at least 3 packets, to prevent an overflow due to packets on their way while a status packet requesting to stop transmission is being sent. Collector buffers 262 optionally have a size corresponding to less than 50 clock cycles, less than 30 clock cycles or even less than 10 clock cycles or less than 5 clock cycles. In some embodiments, collector buffers 262 are on the average smaller than driver buffers 260. Optionally, the sizes of the buffers depend on the clock rates of the corresponding points and/or a desired transmission reliability level requested by the user.

Drivers 212 and/or collectors 220 optionally provide status information on the occupancy of their buffer 260, 262 to controller 230, which generates status report packets which contain the buffer occupancy information and transmits them to communication unit 108, as discussed hereinbelow. The status packets are optionally used by communication unit 108 to compensate for clock drifts between the clock signals of target FPGA 102, which are used by drivers 212, and the clock signal of communication unit 108. In addition, the buffer occupancy information from collectors 220 is optionally used by controller 230 in scheduling the generation of data packets transmitted to communication unit 108.

Drivers 212 optionally receive a ready signal from the user integrated circuit of the FPGA target 102. In cases in which the target FPGA 102 deselects the ready line, indicating the drive point 254 is stopped and should not be driven, driver 212 stops providing driving signals to the drive point. In addition, in order to prevent the buffer of the driver 212 from overflowing, controller 230 transmits an urgent status packet to communication unit 108 instructing it to stop transmitting signals for the drive point 254.

In some embodiments of the invention, drivers 212 collectors 220 and/or other sub-units of agent 104 include error registers (not shown) whose content is sent to computer 110 in one or more status packets when an error occurs. Alternatively or additionally, drivers 212 collectors 220 and/or other sub-units of agent 104 include status registers (not shown), the contents of which are exported to computer 110 in status packets, periodically and/or whenever the content of the status packet changes.

### Triggering

In some embodiments of the invention, the decisions of when to begin and/or end collecting of signals from a collection point 252 are made by computer 110 and accordingly computer 110 transmits begin and/or end instructions to embedded agent 104. Optionally, computer 110 provides instructions about the drivers and/or collectors that are to be enabled and provides general triggering and stopping instructions which begin and end the operation of all the collectors and/or drivers. Alternatively, start and stop commands are provided to each collector 220 and/or driver 212 separately. In some embodiments, computer 110 transmits to controller 230 triggering commands which include a condition and an act to be performed when the condition occurs. Controller 230 monitors the conditions and when a condition is met it instructs the relevant collector 220 to perform the act associated with the condition.

In some embodiments of the invention, collectors 220 continuously collect and store signals from the collection points 252 in respective buffers 260, overwriting previously stored signals in the buffer. When an instruction to begin collecting signals is received, the collector 220 transmits the collected signals from a predetermined time before the triggering event occurred and/or before the collection instruction was received, allowing analysis of signals from before the triggering event occurred. These pre-triggering signals are optionally transmitted along with signals collected after the triggering. Alternatively or additionally, collector 220 continuously transmits collected signals to communication unit 108, where they are cyclically buffered and overwritten. When a triggering event occurs, communication unit 108 is notified and begins transferring the collected signals to computer 110 or otherwise storing the signals for later usage, instead of overwriting them.

Optionally, the time before the triggering in which data is collected is configurable by the user and depends on the sizes of buffers 260. The amount of pre-triggering signals is optionally indictable by the user in terms of time, size and/or clock cycles. The predetermined time before the triggering event optionally includes at least 1 second, at least 5 seconds or even at least 10 seconds.

In some embodiments, each collector 220 includes a triggering unit 242, which monitors one or more internal lines of target FPGA 102 and begins data collection when a predetermined condition is met. Optionally, triggering unit 242 comprises a vector reference register, the content of which is compared to the one or more internal lines and when a match is identified, data collection begins. The data collection is optionally performed for a predetermined time window and/or amount of data (e.g., 200 Mbytes, 1 Gbyte), or is performed until an instruction from computer 110 to stop data collection is received. Further alternatively, the data collection is performed until an additional triggering event occurs.

The content of the vector reference register is optionally set by a user from computer 110 by a control packet transmitted to collector 220 or controller 230. The contents of the vector reference register are optionally continuously compared to a time window of the one or more internal lines. The time window is optionally over 32 or 64 cycles, although other window sizes may be used. In some embodiments, triggering unit 242 additionally comprises a mask register which indicates which bits of the reference register need to match the time window of the one or more internal lines in order to declare a match. The one or more monitored lines may be the same lines whose data is exported in case of a match or may be a different line.

Alternatively or additionally to having a triggering unit 242 in each collector 220, controller 230 may include a triggering unit which determines the beginning of collection by all collectors 220 and/or the beginning of signal driving by all of drivers 212.

Alternatively or additionally to beginning the data collection by triggering units 242, controller 230 receives control packets from communication unit 108 which instruct it as to the beginning and ending of data collection at each of the points 252 and 254.

Optionally, each driver 212 drives a single drive point 254. Alternatively, one or more sub-units, such as the triggering units, are shared by a plurality of drivers 212 and/or collectors 220.

### Packet Structure

In some embodiments of the invention, three types of packets are used: data packets which carry data from collectors 220 to communication unit 108 and from communication unit 108 to drivers 212, control packets which carry instructions from communication unit 108 to target FPGA 102 and status packets which carry status reports from target FPGA 102 to communication unit 108.

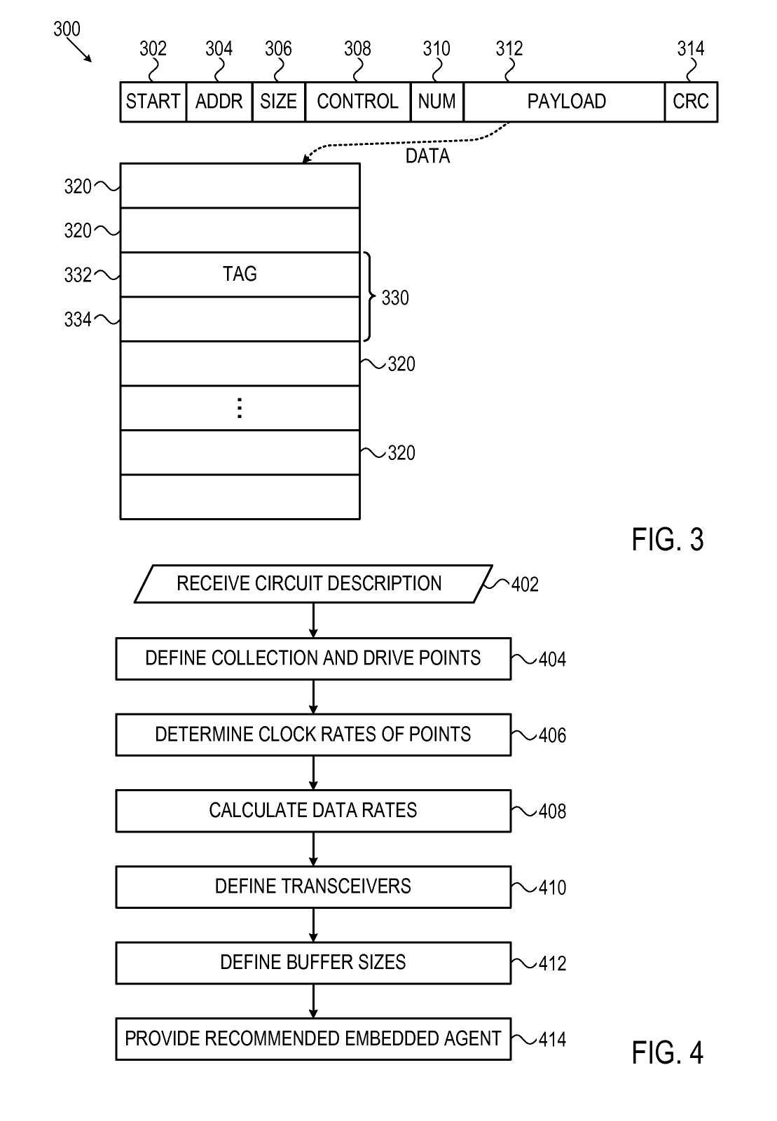

FIG. 3 is a schematic illustration of a packet format 300, used in accordance with an embodiment of the invention. Each packet includes, in accordance with format 300, a start word 302 common to all packets (e.g., having the value 0xc5b1), an address 304 identifying a source collector 220 (for packets transmitted from FPGA 102) or destination driver 212 (for packets transmitted to FPGA 102) in target FPGA 102. Packet format 300 additionally includes a size 306 of the payload, for example stated in terms of a number of valid words, a control word 308, a packet number 310, a payload field 312 and a checksum field 314. Naturally, other packet structures may be used, for example including a subset of the fields in packet format 300 and/or one or more additional fields, such as fields indicating whether coding is used and/or a type of coding, switching and/or routing information, clock drift information for synchronization and/or triggering information.

The control word 308 optionally indicates the type of the packet (e.g., data, control, status) and an indication of whether the packet is a last packet for the corresponding drive or collection point.

The packet number 310 is optionally assigned separately for each collector 220 and/or driver 212, such that packets of different drivers 212 may have the same number. Alternatively, each collector 220 and/or driver 212 is assigned a different packet number range.

The payload field 312 in data packets optionally comprises words 320 including a predetermined number of bits of data. In some embodiments, the words have a length of 64 bits, although other sizes may be used. In some embodiments, payload field 312 may include in addition to data words also metadata sections 330, for various control instructions, such as for indicating data that should be repeated several times and/or for instructing to insert a gap of arbitrary data into a corresponding buffer 260, instead of transmitted data. Optionally, a metadata section 330 includes a Metadata tag 332 which indicates that the signals belong to a metadata section 330 and are not regular data words, and then the specific metadata instructions 334. Other methods may also be used to indicate the position of metadata in payload 312, for example an indication in the header of the packet.

The metadata instructions 334 for repetitions of data optionally include a code word indicating that the metadata relates to repetitions, a block which is to be repeated, a length of the repeated block and the number of times the block is to be repeated. To indicate a gap of no data, the metadata instructions 334 optionally include a code word indicating that the metadata relates to gap and a gap length. The metadata serves in a compression scheme which reduces the amount of data that needs to be transmitted between embedded agent 104 and communication unit 108. It is noted that other compression methods may be used, including, for example, Hoffman coding.

The payload field 312 of control packets optionally includes fields for indicating beginning, ending and/or pausing of transmissions. Each control packet is optionally assigned to a single task. Alternatively, some control packets may be assigned to a plurality of tasks. The payload field 312 of control packets optionally includes in addition to an indication of the task to which the packet relates, an identification of the drive point 254 or collect point 252 to which the packet relates. In some embodiments of the invention, the payload of the control packet includes a single control word which indicates the task and the point to which it relates. Optionally, for speed of operation, different bits of the control word are used to indicate the different tasks, in order to avoid the need for a decoder which is used in embodiments in which a multi-bit code word is used to indicate the task. In addition, in some embodiments, different fields in the control word are used to identify the specific drive point or collector point to which the control packet relates, so that a multiplexer for driving the point identification is not required. Control instructions in the control packets may include, for example, reset instructions and/or triggering and collector or driver enabling instructions.

The payload field 312 in status packets optionally includes global status information relating generally to FPGA agent 102, status information relating to a specific collector or driver and/or status information relating to a specific collector or driver point. The status information may include, for example, contents of an error register, contents of a status register or an indication of the amount of memory used in a driver buffer. The global status information optionally indicates for each driver and/or collector whether it is enabled and working.

Alternatively or additionally to using separate control and/or status packets, some control and/or status data is embedded in data packets as metadata and/or in packet headers.

Optionally, a single status packet relates to all the drivers and collectors in FPGA agent 102. Alternatively, separate status packets are provided for the drivers and the collectors or separate status packets are provided for separate drivers and/or drive points.

In some embodiments of the invention, all packets, both data and control packets, have the same size, for example 1024 bits, for simplicity of handling. When necessary, padding packets are used to complete to the required packet size. Alternatively, different size packets are used, according to the amount of data that needs to be transmitted. In some embodiments, all data packets have the same size, e.g., 1024 bits, and control packets all have a same size, but smaller than the size of the data packets, e.g., 128 bits. In other embodiments, packets may have any size or any of a predetermined set of allowed sizes and each packet is given an allowed size closest to its data size.

### Operation Flow

Upon receiving a packet, embedded agent 104 optionally checks that the packet is valid. Valid data packets are transferred to their destination driver for placing their data content in the respective buffer 260. Control packets are transferred to controller 230, which according to their content enables or disables operation of drivers 212 and/or collectors 220 and/or performs other indicated control tasks.

In some embodiments of the invention, each time a control packet is received, a status packet is generated for the driver or collector to which the control packet relates. The status packet may serve as a simple acknowledgement and/or may provide in addition to an acknowledgement of the received control packet additional status information. In other embodiments, status packets are generated periodically, not in response to receiving a control packet. The status packets indicate the amount of data in each buffer 260, such that communication unit 108 can decide the order in which the data of different buffers 260 is transmitted to FPGA agent 102, in a manner which prevents overflows and underflows.

Transmitter 216 repeatedly takes signals from buffers 262, generates packets from the signals and the packets are transmitted through transceivers 206 to communication unit 108. The generation of packets is repeated continuously, as long as there are operative collection points 252 and/or there is data in buffers 262.

Controller 230 optionally receives occupancy indications for each of the buffers 262 and accordingly instructs transmitter 216 on a next buffer 262 from which signals are to be transmitted. Alternatively or additionally, controller 230 estimates the occupancy of one or more of buffers 262 according to the clock rate of the collection point corresponding to the buffer 262, the size of the buffer and the previous time at which signals were taken from the buffer. Optionally, transmitter 216 always selects the buffer 262 which is closest to being full. Alternatively, controller 230 may schedule generating packets from the buffers in a predetermined order, for example using a round robin scheduling, and deviate from the predetermined order only when one of the buffers is determined as being nearly full. Further alternatively, other methods of scheduling the buffers may be used.

Controller 230 is optionally configured to monitor the rate at which buffers 262 are filled, in order to determine the exact clock rates of the collection points 252. In some embodiments of the invention, controller 230 operates at a relatively high rate, higher or equal to the rates of the collection points, determines in each clock cycle whether each of buffers 262 is empty or full and accordingly the clock rate of the collector 220 is determined. In some embodiments, controller 230 is configured to connect a specific collection point to a specific drive point upon an instruction from computer 110, for example for testing the operation of agent 104.

Agent 104 is optionally separate from the tested integrated circuit in target FPGA 102 in that each has a separate reset.

### Communication Unit

Referring in detail to communication unit 108, in some embodiments as shown in FIG. 1, unit 108 comprises a target FPGA interface 162, for communicating with embedded agent 104, a processor 166, DMA units 182, a memory unit 168 and a network interface 164. computer Network interface 164 may be, for example, an Ethernet interface, non-network interface, a SATA, USB, PCIe interface or any other suitable interface for network communications. In some embodiments, network interface 164 comprises a plurality of different protocol units for communications in accordance with different protocols, allowing communications with differently configured computers 110.

Communication unit 108 receives from computers 110 drive data for transmission to embedded agent 104 and buffers it in memory unit 168. Based on status packets received from embedded agent 104, processor 166 regulates the flow of the drive data in memory unit 168 to agent 104, in a manner which prevents overflows and/or underflows in buffers 260. Collected data received from agent 104 is buffered in memory unit 168 and is transmitted to computer 110 or computers 110. Memory unit 168 is optionally sufficiently large to accumulate data corresponding to at least 20, 40 or even 100 points for at least 5 seconds, one minute, 5 minutes, or even more. In some embodiments, memory unit 168 has a size of at least 4 Gigabytes or even at least 8 Gigabytes. In some embodiments, memory unit 168 has a size of at least 100 Gbytes or even at least 500 Gbytes. Optionally, in these embodiments, memory unit 168 comprises a solid state disk (SSD). Memory unit 168 optionally has a separate sector corresponding to each buffer 260 and 262. The sizes of the sectors may be predetermined or dynamically adjusted according to utilization. In some embodiments, the sizes of the sectors are adjusted according to the clock rates of the corresponding drive or collection points. The sectors are optionally assigned memory in blocks of 1024 bytes, i.e., the size of each sector is divisible by 1024, for ease of memory access. Alternatively, any other block size which is compatible with the hardware characteristics (e.g., structure, operation rate, and/or other properties) of communication unit 108, is used.

Optionally, the sectors corresponding to one or more drivers 212 are adjacent each other in memory unit 168 to allow faster access for several packets together. The starting points of the sectors are optionally held in dedicated registers to allow for fast address determination.

Communication unit 108 may optionally operate in both an offline mode in which drive and collect data is stored in memory unit 168 and the collected data is retrieved by a user after the test is completed, by connecting computer 110 to communication unit 108 and an online mode in which collected data is transmitted to computer 110 in real time during the test and driver data is received from computer 110 during the test. Alternatively, communication unit 108 operates only in the online mode, in which case a relative small memory unit 168 may be used as it is only needed for buffering. Further alternatively, communication unit 108 only operates in offline mode.

FPGA interface 162 optionally comprises a plurality of transmission units corresponding respectively to interfaces 208 of embedded agent 104. Packets for transmission to agent 104 are optionally accumulated in a buffer in processor 166 or memory 168 and each time one of the transmission units is available it takes a next packet from the buffer.

The packets exchanged between communication unit 108 and embedded agent 104 are optionally of a size most optimally handled by memory unit 168 and/or DMAs 182, for example 256 bytes. Optionally, each packet received from embedded agent 104 is encapsulated by processor 166 and/or by a DMA 182 in accordance with the protocol of network interface 164. Each packet may be encapsulated separately, or a plurality of packets may be encapsulated together into a single message. In some embodiments of the invention, the messages are of an optimal size for accessing memory unit 168 at high speeds, for example, 1024 bytes, not including message headers. Optionally, each data message carries several packets and not portions of packets, for example up to 4 data packets. Optionally, the number of packet included in a single message transmitted to computer 110 is the smallest number of packets that together is of a size considered optimal in accessing memory unit 168. Control and status packets are optionally handled by communication unit 108 and are not forwarded to computer 110. Alternatively, some control and/or status packets are handled locally by communication unit 108, while other control and/or status packets are forwarded to computer 110. Further alternatively, all control and/or status packets are forwarded to computer 110. Optionally, control and status packets are given priority in the forwarding. Possibly, even if data packets are combined into large messages, control and/or status packets are forwarded on their own, avoiding any delay required for combining packets into a larger message. In some embodiments of the invention, separate ports (e.g., Ethernet ports) are used for control and/or status packets and for data packets by computer 110 in communicating with communication unit 108. The port for control packets is optionally given higher priority to ensure fast transmission of control packets.

In some embodiments of the invention, processor 166 checks the validity of packets it forwards. Alternatively, processor 166 may operate in a full mode in which packet validity is checked or in a light mode in which validity is not checked, for example in order to achieve high transmission rates.

In some embodiments, the transfer of packets between memory 168 and interfaces 162 and 164 is performed by dedicated DMA (Direct Memory Access) units 182. Optionally, communication unit 108 includes four DMAs 182, two DMAs for transferring data between interface 164 and memory 168, one for transferring data into the memory and to transferring data from the memory, and two DMAs for transferring to and from interface 162. DMAs 182 are optionally implemented by hardware. Processor 166 is optionally a dedicated hardware unit designed specifically for operation in communication unit 108, so that processor 168 and DMAs 182 operate at high speeds, sustaining throughput of write/read accesses to memory 168 at more than 70%, more than 80%, or even more than 90% of the theoretical memory throughput. Total data rate through communication unit 108 is optionally more than 20 Gigabit per second, more than 40 Gigabit per second or even 80 Gigabits per second.

### FPGA Configuration

FIG. 4 is a flowchart of acts performed by a builder software on computer 110 in preparation for testing and/or validation of a target FPGA 102, in accordance with an embodiment of the invention. A file description of the target integrated circuit, for example in a Register-transfer level (RTL) language, such as Hardware description language (HDL), or Verilog, is received (402) by the builder software from the user. The received description is optionally simulated by simulator 116 and when the user is satisfied the RTL description undergoes parsing and analysis by a synthesis tool 114, such as Quartus and is converted into a Netlist description. The Netlist description undergoes Place and routing (P&R) and timing, which results in a layout of the integrated circuit. It is noted that computer 110 may also receive the layout itself or a Netlist description, for example from a different computer or through a suitable design tool.

The circuit layout is optionally presented to the user, who defines (404) collection and drive points using a dedicated search engine. In some embodiments, the user also defines triggering points which are each monitored by one or more of the triggering units. The software then determines (406) clock rates of the defined points. The transmission data rate required to support the defined collection and drive points according to their defined data rates is calculated (408) and accordingly a required number of transceivers 206 and 208 are defined (410) and their transmission rates are adjusted. In addition, the sizes of buffers 260 and 262 are defined (412) in a manner which reduces the chances of underflows and overflows to below a desired level.

The builder software provides (414) a recommended embedded agent circuit description in HDL or Netlist along with an indication of a failure probability, area requirements and/or number of transceivers 206 and 208. The user may request to adjust one or more of the parameters, for example to reduce the risk of failure or to reduce the resources required by embedded agent 104.

The embedded agent description is then combined with the description of the user's circuit and together they are compiled, converted into an integrated circuit layout. Alternatively, the embedded agent description is compiled separately and its Netlist or layout is merged with the corresponding Netlist or layout of the user's integrated circuit. The user may then test the target FPGA using the various tools of computer 110.

In some embodiments of the invention, along with defining (404) collection and drive points, the user may define additional keep points which may be desired to be used as collection or drive points at a later time.

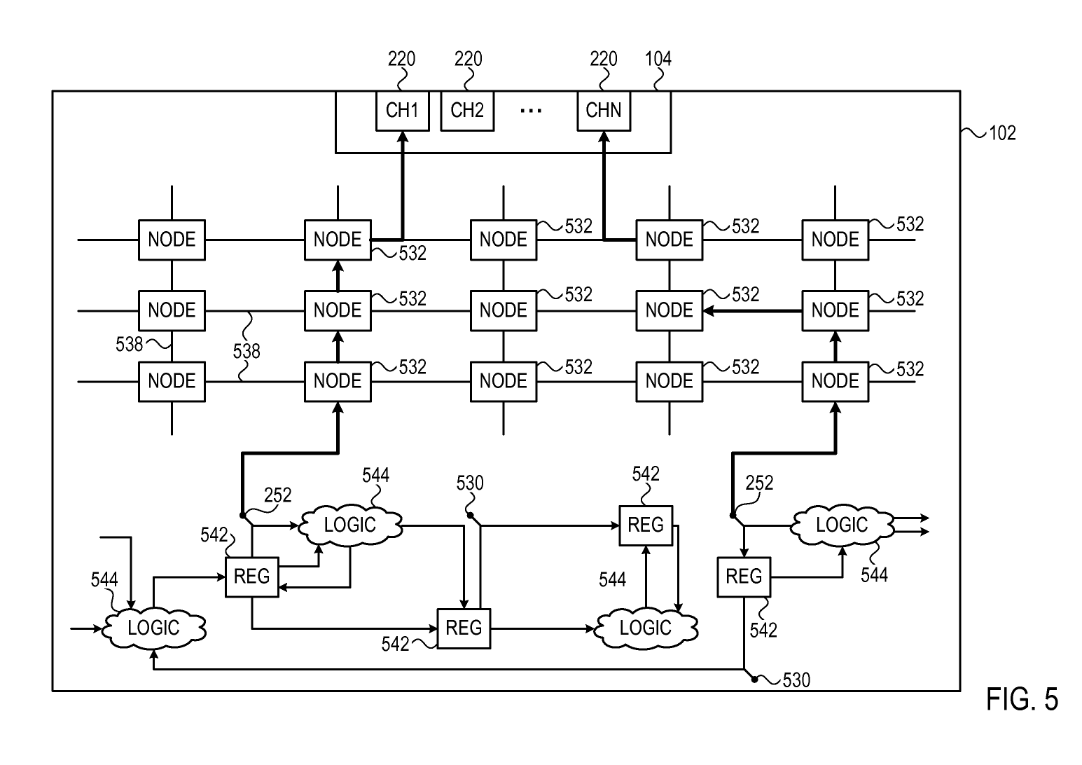

FIG. 5 is a schematic illustration of target FPGA 102, in accordance with an embodiment of the invention. In FIG. 5, the elements of the user circuit are represented schematically by several registers 542 and logic clusters 544. It will be understood that registers 542 and logic clusters 544 are shown to schematically represent the user's integrated circuit, and usually there are many more logic and register elements. Target FPGA 102 includes used defined collection points 252, which are connected respectively to collectors 220 of agent 104. In some embodiments, signal transfer nodes 532 are distributed throughout the area of target FPGA 102, to connect the collection points 252 to collectors 220. It is noted that nodes 532 are shown together, above the user logic and registers only for clarity, and generally the nodes 532 are intended to be dispersed between the logic elements of the user's circuit. Signal transfer nodes 532 are optionally passive nodes which simply reserve points and connecting links 538 for connecting collection points 252 to connectors 220. Alternatively or additionally, one or more of nodes 532 serves as an active repeater, increasing the amplitude and/or timing of the signals so that they properly reach their collector 220.

In some embodiments of the invention, the user indicates using the builder software keep points 530 which are to be reserved in case the user desires at a later time to connect them to collectors 220. Optionally, keep points 530 are reserved by indicating in the RTL or Netlist description that the point should not be merged with other points during the process of preparing the layout of the FPGA.

In some embodiments, nodes 532 are distributed throughout target FPGA 102 in a sufficient density that allows connecting to any point, regardless of the actual locations of collection points 252 and/or keep points 530. Alternatively, the distribution of nodes 532 is determined based on the locations of collection points 252 and keep points 530, such that in areas in which there or no collection or keep points unnecessary nodes 532 are not placed.

If at a later time the user requests to connect one of the keep points 530 to a collector 220, instead of one of collection points 252, the builder software changes the connections at the FPGA layout level, for example using an engineering change order (ECO) tool, thus avoiding the need to recompile the entire circuit description, a process which may be time consuming. In changing the connections, the ECO tool optionally first cancels the connection of the old collection point 252 to its collector 220 and then finds a path from the collector 220 to the indicated new keep point 530 and adds the path. The path is optionally selected to be the shortest available path.

While the above description with reference to FIG. 5 relates to collection points, similar methods may be used in defining drive points. Optionally, a keep point 530 may be used as either a collection point or a drive point according to the user's selection indicated to the ECO tool.

In other embodiments of the invention, drivers 212 and/or collectors 220 may be connected through multiplexers to a plurality of drive or collection points. During use, the user selects which point he wants to see in input to computer 110 and then a control packet or other control signal is transmitted to agent 104, indicating the point to be connected to the collector or driver.

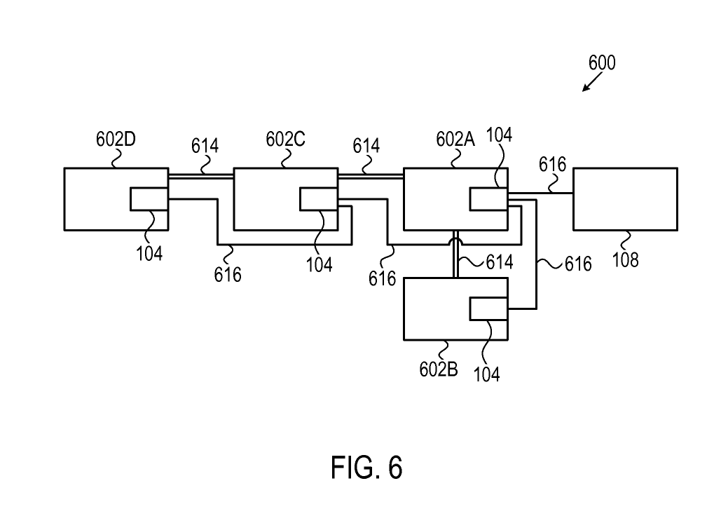

FIG. 6 is schematic illustration of an FPGA testing setup 600, in accordance with an embodiment of the invention. In setup 600 communication unit 108 communicates with a plurality of cascaded target FPGAs 602 (marked 602A, 602B, 602C, 602D). Each of target FPGAs 602 includes an embedded agent 104. In addition to the tasks of the agent discussed above, agents 104 of FPGAs 602 are configured to identify packets that are directed to a different FPGA 602.

In some embodiments of the invention, FPGAs 602 are connected to each other through data links 614 and separate signal export links 616 are used to connect their agents 104 to each other and to communication unit 108. The widths of the signal export links 616 are selected to accommodate all the transmissions that pass on the link. For example, the link connecting agent 104 of FPGA 602A to communication unit 108 needs to have sufficient bandwidth to carry the signals to and from all the FPGAs 602 of setup 600, while the link 516 connecting the agents 104 of FPGAs 602A and 602B needs to have bandwidth sufficient for the signals of the agent 104 of FPGA 602B.

In the above description, the data is exchanged between communication unit 108 and embedded agent 104 in packets. The use of packets allows for various advantages, such as easily carrying data from different sources (e.g., different collection points, data and control) on the same channels, thus achieving better utilization of the channels. In addition, the use of packet transmission allows relatively easy utilization of different physical layer protocols and separate planning of each level of the protocol stack. It is not, however, that in some embodiments, some or all of the data and/or control packets are transmitted using a non-packet streaming method, for example in order to provide compatibility to old systems.

Furthermore, while in the above description all the computers 110 are connected to embedded agent 104 through a single communication unit 108, in other embodiments a plurality of communication units 108 are used. For example, one or more first pins of the chip encasing the integrated circuit are connected to a first communication unit and one or more second pins of the chip being connects to a second communication unit 108. Each of the communication units is optionally connected to all of computers 110. Alternatively, each communication unit 108 is connected to one or more different computers 110. Optionally, the packets include in addition to an on-chip address also a communication unit 108 address which is used to route the packets to their destination. In other embodiments, a first communication unit 108 is connected to the embedded agent 104 and one or more second communication units connect the first communication unit to the computers 110.

It is further noted that communication unit 108 has the advantage of providing faster communications with agent 104 than can generally be achieved by a general purpose computer. The faster communications reduces the required size of buffers in agent 104 and thus reduces the chip area of target FPGA 102 that is consumed by agent 104. The memory of communication 108 thus serves to reduce the required memory in agent 104. Still, in some embodiments, for example when a very fast computer 110 is used and/or when only a minimal number of points are driven or monitored, computer 110 is connected directly to agent 104 without an intermediate communication unit 108.

While the above description relates to sensing internal signals from an FPGA integrated circuit, the methods and/or apparatus of the present invention may be used also for other types of integrated circuits, such as Programmable Logic Devices (PLD), Application Specific Integrated Circuits (ASIC) and Application Specific Standard Products (ASSP). When internal signals of an integrated circuit operates at speeds beyond the available transmission rates, the embedded agent 104 may be configured to provide signals from low clock rate areas of the integrated circuit and/or to transmit signals at a near-operation-rate, for example providing a sample every five or ten clock cycles.

### Computer

The collected signals transmitted to computer 110 may be analyzed using any method known in the art. For example, the collected signals may be graphically displayed on a waveform viewer and/or on a HEX editor for manual inspection and analysis by user. Alternatively or additionally, the collected signals may be provided to an RTL (Register-transfer level) or ESL (Electronic system level) Testbench environment designed to simulate part of all of the integrated circuit in the target device. The Testbench may be used to automatically check validity and/or correctness of the collected signals and/or to generate the drive signals provided to drive points.

In some embodiments, the analysis of the signals includes reconstructing higher level structures, such as communication packets, from the signals. For example, if the signals at a specific collection point are supposed to represent packets according to a specific protocol, such as TCP, UDP and/or IP, computer 110 optionally runs a software packet analyzer which the packets passing at the point, from the signals and optionally indicates errors and/or unexpected values in the reconstructed packets. The packet analyzer is optionally used to view the contents of the packets in any desired protocol layer, including the payload. In some embodiments, when data is collected from a plurality of different points representing communication packets or other data structures, the packet analyzer on computer 110 may compare the packets at the different points. The travel of the packets between different points may be presented to the user graphically on a map of the points or in any other method.

Computer 110 is used to specify drive signals to be generated. Optionally, the user may indicate the desired signals in various levels and computer 110 converts the user request into the actual drive signals. For example, the user may provide data which is to be transmitted in the form of UDP packets at a specific drive point and computer 110 generates packets for the data and drives the point with the bits of the generated packets.

In some embodiments, computer 110 passes the signals of one or more collection points to a modeling program, such as Matlab or Simulink. The modeling program may be used to filter the signal, or to perform analysis in time and/or frequency domain. This analysis is particularly useful when the signals of a collection point represent a physical quantity, such as samples of an analog-to-digital converter (ADC), where the analog signal corresponds to a voltage level representing an electromagnetic signal.

The modeling program may also be used to generate signals of a desired characteristic for driving one or more drive points. For example, the modeling program may generate a digitally sampled analog signal which corresponds to a simulative electromagnetic signal, which is meant to drive a digital output which drives a digital-to-analog converter (DAC).

In analyzing signals collected from one or more memory mapped busses (e.g. AMBA AXI), the collected signals are optionally transformed into a transaction representation, by identifying signal sequences which together form a bus transaction. A bus transaction may include, for example, the fields: transaction timetag, read/write indication, length, Bus-master ID number, address, latency. The fields of the bus transaction are optionally configured into the analysis tool on computer 110, according to the type of the bus being analyzed. Optionally, the analysis tool is configured with field structures of a plurality of different types of buses. The user optionally indicates for each collection point, the type of the bus. Alternatively or additionally, the analysis tool automatically determines the type of the bus, for example by attempting to match the signals passing on the bus with a plurality of different signal structures and selecting a best match.

Optionally, after combining the signals of the bus into transactions, the transactions may be used for statistical analysis of the bus operation. The statistical analysis optionally includes determining for each transaction one or more parameters, such as latency, accessed bank address, accessed row, length and read/write. The user optionally requests information on the general distribution of one or more parameters and/or the dependence of one or more parameters on one or more other parameters. The information may be provided to the user in various methods including text, table and graph formats. In some embodiments of the invention, the average throughput, busy state and/or latency of the bus for a given period length are determined for various time periods or in general. Alternatively or additionally, the statistical correlation or covariance between the throughput or latency of any two of the clients of the bus is calculated and presented to the user in text, table and/or graph formats.

The term real-time transmission refers herein to transmissions performed within a short time from when the data was generated, such as within less than a minute or less than a second from the time the data was generated. In some embodiments of the invention, the data is transmitted to or from embedded agent 104 within less than 100 clock cycles or even less than 50 clock cycles between its transmission and when the data was generated and/or when the data is applied to a drive point.

The term operation rate of a signal refers herein to a rate at least of the order of the normal operation rate of the signal.

### CONCLUSION

It will be appreciated that the above described methods and apparatus are to be interpreted as including apparatus for carrying out the methods and methods of using the apparatus. It should be understood that features and/or steps described with respect to one embodiment may sometimes be used with other embodiments and that not all embodiments of the invention have all of the features and/or steps shown in a particular figure or described with respect to one of the specific embodiments. Tasks are not necessarily performed in the exact order described.

It is noted that some of the above described embodiments may include structure, acts or details of structures and acts that may not be essential to the invention and which are described as examples. Structure and acts described herein are replaceable by equivalents which perform the same function, even if the structure or acts are different, as known in the art. The embodiments described above are cited by way of example, and the present invention is not limited to what has been particularly shown and described hereinabove. Rather, the scope of the present invention includes both combinations and subcombinations of the various features described hereinabove, as well as variations and modifications thereof which would occur to persons skilled in the art upon reading the foregoing description and which are not disclosed in the prior art. Therefore, the scope of the invention is limited only by the elements and limitations as used in the claims, wherein the terms “comprise,” “include,” “have” and their conjugates, shall mean, when used in the claims, “including but not necessarily limited to.”

1. A method of connecting to an integrated circuit, comprising:
providing a target integrated circuit with an embedded agent for exporting signals;
operating the integrated circuit;
collecting data signals from one or more collection points in the integrated circuit, by the embedded agent, at least at a clock rate of operation of the integrated circuit at the one or more collection points, in parallel to the target circuit operation;
inserting the collected data signals into packets, by the embedded agent; and
transmitting the packets to a unit external to the integrated circuit, in real time.

2. The method of claim 1, comprising receiving, by the embedded agent, packets of data from the external unit and placing data signals from the packets onto one or more drive points defined in the integrated circuit.

3. The method of claim 2, wherein placing data signals from the packets onto one or more drive points defined in the integrated circuit is performed at a rate of at least one tenth of the clock rate at the drive points.

4. The method of claim 2, comprising applying an error detection check to the received packets, by the embedded agent.

5. The method of claim 4, comprising applying an error correction method to received packets detected as having errors.

6. The method of claim 2, comprising receiving by the embedded agent of reordered packets from the external unit, reordering the packets according to identification numbers in the packets, and placing signals from the packets onto one or more drive points defined in the circuit design.

7. The method of claim 1, comprising compressing the signals from the collection points before transmission to the external unit.

8. The method of claim 7, wherein compressing the signals comprises replacing repeated sequences by metadata.

9. The method of claim 7, wherein compressing the signals comprises replacing a window of data by metadata which is a function of a previous window of data.

10. The method of claim 1, wherein the one or more collection points comprise a plurality of collection points operating at a plurality of different clock rates.

11. The method of claim 10, comprising continuously calculating temporal rates of the collection points by the external unit and presenting the signals from the different points on a shared timeline.

12-22. (canceled)

23. The method of claim 1, wherein the embedded agent includes respective buffers for each collection point in the circuit design and comprising transmitting periodic status packets, including indications of the occupancy of the buffers, from the embedded agent to the external unit.

24. The method of claim 1, wherein inserting the collected signals into packets comprises inserting into packets with a header including an address field identifying a unit of the embedded agent.

25. The method of claim 1, wherein the embedded agent is implemented by a hardware design.

26. The method of claim 1, wherein the embedded agent including all on-chip memory for storing collected signals occupies less than 2% of the area of the integrated circuit.

27. The method of claim 1, wherein the embedded agent includes for each collection point a respective buffer which has memory sufficient for storing data collected in no more than 50 clock cycles.

28. The method of claim 1, comprising receiving by the embedded agent collected signals from one or more additional integrated circuits and forwarding the received signals to the external unit.

29. An integrated circuit, comprising:
a target user circuit;
an embedded agent including:
one or more collectors connected to respective collection points in the user circuit, configured to collect signals from the respective collection points, at least at a clock rate of operation of the integrated circuit at the collection point, and to insert the collected signals into packets; and
one or more transmitters configured to transmit packets from the one or more collectors to a unit external to the integrated circuit, in real time.

30. (canceled)

31. The integrated circuit of claim 29, wherein the one or more collectors comprise buffers having a total capacity for each collection point, of less than 5 Kbytes.

32. The integrated circuit of claim 29, wherein the embedded agent comprises an error detection unit adapted to add an error detection code to packets generated by the collectors.

33. The integrated circuit of claim 29, wherein the embedded agent comprises a compression unit configured to compress signals collected by the collectors.

34. (canceled)

35. A method of connecting to an integrated circuit, comprising:
providing a target integrated circuit with an embedded agent for exporting internal signals;
operating the integrated circuit, such that a plurality of different areas of the integrated circuit operate in different clock domains;
collecting data signals from a plurality of collection points in respective different areas having different clock domains, at least at the clock rates of the collection points, in parallel to the circuit operation; and
transmitting the collected data signals to a unit external to the integrated circuit, in real time.

36. The method of claim 35, wherein the embedded agent includes a respective buffer in which the signals are buffered until they are transmitted, for each collection point, and wherein at least two of the buffers have different sizes.

37. (canceled)

38. A method of non-intrusive output of signals from an integrated circuit, comprising:
providing a target integrated circuit with an embedded agent for exporting internal signals, the embedded agent including a triggering unit;
operating the integrated circuit;
collecting signals from one or more collection points at least at the operation rate of the integrated circuit, in parallel to the circuit operation; and
transmitting the collected signals to a unit external to the integrated circuit, in real time,
wherein at least one of the collecting and transmitting is initiated or terminated by the triggering unit.

39. The method of claim 38, comprising monitoring the signals on one or more points of the integrated circuit by the triggering unit and initiating or terminating the collecting or the transmitting, responsively to identifying a user-selected sequence on the one or more points.

40. The method of claim 39, wherein monitoring the one or more points comprises monitoring at least one point is different form the one or more collection points from which signals are collected.

41. The method of claim 40, wherein monitoring the one or more points comprises monitoring only points different form the one or more collection points from which signals are collected.

42. The method of claim 38, wherein collecting the signals is performed continuously and wherein transmitting the collected signals is initiated responsive to identification of an event by the triggering unit.

43-51. (canceled)
